(19) United States
(12) Patent Application Publication
(10) Pub. No.: US 2010/0295759 A1
(43) Pub. Date: Nov. 25, 2010

(54) ORGANIC ELECTROLUMINESCENCE DISPLAY DEVICE

(75) Inventor: Masahiro Tanaka, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignees: Hitachi Displays, Ltd.; CANON KABUSHIKI KAISHA

(21) Appl. No.: 12/780,229

(22) Filed: May 14, 2010

(30) Foreign Application Priority Data
May 20, 2009 (JP) 2009-121669

(51) Int. Cl. G09G 3/30

(52) U.S. Cl. 345/76

(57) ABSTRACT

A solid-sealed organic electroluminescence display device is provided with means of preventing the occurrence of a dark spot in the market, due to the degradation of an organic EL light emitting layer by water entering from a pinhole of a sealant. In order to prevent the degradation of the organic EL layer by water, a first inorganic film, an organic flattening film, and a second inorganic film are formed on an upper electrode. Water entering from the pinhole in the second inorganic film diffuses into the organic flattening film, and degrades the organic EL layer in several months, resulting in a defect in the market. In order to prevent this, a material capable of reacting with oxygen or water and exhibiting color is added to the organic flattening film. Then, the defective organic electroluminescence display device is picked up and eliminated prior to delivery to the market.

### CLAIM OF PRIORITY

The present application claims priority from Japanese Patent Application JP 2009-121669 filed on May 20, 2009, the content of which is hereby incorporated by reference into this application.

### FIELD OF THE INVENTION

The present invention relates to an organic electroluminescence display device, and more particularly to a highly reliable organic electroluminescence display device capable of suppressing an occurrence of a dark spot or other defects caused by water.

### BACKGROUND OF THE INVENTION

In an organic electroluminescence (EL) display device, an organic EL layer interposed between a lower electrode and an upper electrode. The light emission of the organic EL layer of the organic EL display device is controlled by applying a certain voltage to the upper electrode, and by applying a data signal voltage to the lower electrode. The data signal voltage is supplied to the lower electrode through a thin film transistor (TFT). The organic EL layer emits light of red, green, or blue depending on a material of a light emitting layer. Pixels each having such organic EL layer and TFT are arranged in a matrix form, in which the light emission of each pixel is controlled to form an image.

The organic EL display device is divided into two types, bottom emission type and top emission type. The bottom emission type extracts the light emitted from the organic EL layer in the direction of a glass substrate in which the organic EL layer and the like are formed. The top emission type extracts the light emitted from the organic EL layer in the reverse direction of the glass substrate in which the organic EL layer and the like are formed. The top emission type has an advantage in that it is possible to form a light emission region also on the region in which the TFT is formed.

The organic EL display device uses an organic EL material having light emission characteristics which are degraded by the presence of water. When the organic EL display device is operated for a long period of time, the area degraded by water does not emit light. This appears as a dark spot in the display area. The dark spot grows as the time passes, causing a defect in an image. Also, the phenomenon of increasing the non-emitting area in the periphery of the pixel, which is called edge growth, occurs by the effect of the water.

In order to prevent the generation or growth of the dark spot or other defective areas, it is necessary to prevent water from entering the organic EL display device, or to remove the entering water from the organic EL display device. For this reason, a technology has been developed to prevent outside water from entering the organic EL display device by sealing a device substrate in which the organic EL is formed. At this time, the device substrate is sealed by a sealing substrate through a seal provided in the periphery thereof. The sealed interior space is filled with an inert gas such as N₂. In addition, a drying agent is provided within the organic EL display device in order to eliminate water entering the organic EL display device. This is called a hollow sealed organic EL display device.

However, the hollow sealed organic EL display device has the following problems. It is difficult to control the gap between the device substrate and the sealing substrate. It is necessary to widely apply a sealing material to bond the device substrate and the sealing substrate together in the periphery in order to prevent water from entering inside. The organic EL material is contaminated by the gas emitted from a sealant for sealing the organic EL display device. The throughput of the organic EL display device is low. There is also a problem with the completed organic EL display device that when an external force is applied to the device substrate or the sealing substrate, the device substrate and the sealing substrate come into contact with each other, causing the organic EL layer to be destroyed.

In order to address the problem of the hollow sealing structure, JP-A No. 156058/2007 describes a technology that forms an inorganic passivation film, an organic flattening film, and an inorganic passivation film on an organic EL display panel in which an organic EL layer and an upper electrode are formed, without using a sealing substrate. Such a sealing structure will be hereinafter referred to as solid sealing.

An electron injection layer of an organic EL layer often uses a metal having a high reactivity, such as alkali metal or alkali earth metal. If water is present, the layer reacts with the water and becomes inactive. For this reason, it is necessary to seal the organic EL layer to prevent the water from entering. In other words, the organic EL display panel formed over the upper electrode is covered by an inorganic passivation film, an organic flattening film, and an inorganic passivation film. This configuration is likely to provide a relatively robust, thin, and low-cost organic EL display device.

However, there is a pinhole in the inorganic passivation film. The pinhole is caused by a foreign substance on the substrate, particles grown by vapor deposition, or other factors. When such a pinhole is present in the inorganic passivation film, the water enters from the pinhole and diffuses into the resin layer to reach the organic EL layer, causing the deactivation of the organic EL layer. The diffusion of the water into the resin layer is slow. As a result, the defect actually occurs in several months to about a year, or at least in a month or more even in an accelerated test.

The defect occurs after the delivery of the product as a defect in the market, resulting in the loss of the trust of the customers. Thus, such a defect should be prevented as much as possible. However, the pinhole is very small and is difficult to be found even with a microscope. It may not be possible to find the pinhole of the passivation film on the device substrate in which an active matrix circuit pattern, organic EL layer, and the like, are formed.

As described above, the conventional technology may not typically be able to find the defect in the passivation film that is likely to cause a defect in the market. Accordingly, it is desirable to provide a solid sealed organic EL display device formed by the inorganic passivation film, the organic flattening film, or the organic resin film and the like, with means capable of detecting the presence of a pinhole in the passivation film, and preventing the organic EL display device having such a problem from being delivered to the market.

### SUMMARY OF THE INVENTION

The present invention solves the above problem by the following means.
(1) There is provided an organic electroluminescence display device including a display area in which pixels, each having a TFT and an organic EL layer interposed between a lower electrode and an upper electrode, are arranged in a matrix form. A first inorganic film is formed on the upper electrode. An organic film is formed on the first inorganic film. A second inorganic film is formed on the organic film. And a material capable of reacting with oxygen and exhibiting color is added to the organic film.
(2) In the organic electroluminescence display device described in (1), the organic film is epoxy resin, or polypropylene resin, or polyethylene resin.
(3) In the organic electroluminescence display device described in (2), the material capable of reacting with oxygen and exhibiting color is indigo carmine or ethylene blue.
(4) In the organic EL display device described in (3), the organic film contains 0.5 to 2 percent by weight of the material capable of reacting with oxygen and exhibiting color.
(5) There is provided an organic electroluminescence display device including a display area in which pixels, each having a TFT and an organic EL layer interposed between a lower electrode and an upper electrode, are arranged in a matrix form. A first inorganic film is formed on the upper electrode. An organic film is formed on the first inorganic film. A second inorganic film is formed on the organic film. And a material capable of reacting with water and exhibiting color is added to the organic film.
(6) In the organic electroluminescence display device described in (5), the organic film is polypropylene resin or polyethylene resin.
(7) In the organic electroluminescence display device described in (6), the material capable of reacting with water and exhibiting color is a mixture of phenolphthalein and sodium carbonate.
(8) In the organic electroluminescence display device described in (7), the organic film contains 0.5 to 2 percent by weight of the material capable of reacting with water and exhibiting color.
(9) There is provided an organic electroluminescence display device including a display area in which pixels, each having a TFT and an organic EL layer interposed between a lower electrode and an upper electrode, are arranged in a matrix form. A laminate film including an adhesive material and a base material are provided on the upper electrode. A pigment is applied to the base material of the laminate film. An inorganic film is formed on the laminate film. And the pigment is a material capable of reacting with oxygen and exhibiting color.
(10) In the organic electroluminescence display device described in (9), the material capable of reacting with oxygen and exhibiting color is indigo carmine or methylene blue.
(11) There is provided an organic electroluminescence display device including a display area in which pixels, each having a TFT and an organic EL layer interposed between a lower electrode and an upper electrode, are arranged in a matrix form. A laminate film including an adhesive material and a base material are provided on the upper electrode. A barrier layer for blocking water is formed on the base material of the laminate film. An inorganic film is formed on the laminate film. And a material capable of reacting with water and exhibiting color is added to the adhesive material.
(12) In the organic electroluminescence display device described in (11), the barrier layer is formed by co-depositing alumina and silica.
(13) In the organic electroluminescence display device described in (11), the material capable of reacting with oxygen and exhibiting color is cobalt chloride.
(14) In the organic electroluminescence display device described in (11), the material capable of reacting with oxygen and exhibiting color is a mixture of sodium carbonate and phenolphthalein.

In the solid sealed organic electroluminescence (EL) display device according to the present invention, it is possible to detect the presence of a pinhole in the interfacial surface of the inorganic passivation film at an early stage. This makes it possible to prevent the defective product in which the pinhole is present, from being delivered to the market. Further, by detecting the pinhole at an early stage, it is possible to detect a problem of CVD or other processes at an early stage. As a result, the production yield can be increased.

Further, in the present invention, the presence of the pinhole in the inorganic passivation film is detected by the color exhibition of the pigment added to the organic flattening film. In this case, when the color exhibition of the pigment can return to transparent, the inorganic passivation film can be formed again after the removal of the water in the organic EL display device. In this way, it is possible to reproduce the organic EL display device with no pinhole.

### BRIEF DESCRIPTION OF THE DRAWINGS

FIG. 1 is a cross-sectional view of an organic EL display device according to the present invention;

FIG. 2 is a perspective view of an organic EL display panel according to the present invention;

FIG. 3 is a cross-sectional view showing the problem of the presence of a pinhole in a third inorganic passivation film;

FIG. 4 shows an example of the occurrence of a dark spot due to the degradation of an organic EL layer by water;

FIG. 5 is a cross-sectional view showing a first embodiment;

FIG. 6 is a perspective view of the organic EL display device, which shows the effect of the first embodiment;

FIG. 7 is a cross-sectional view showing a second embodiment; and

FIG. 8 is a cross-sectional view showing a third embodiment.

### DETAILED DESCRIPTION OF THE PREFERRED EMBODIMENTS

Hereinafter, the present invention will be described in detail through embodiments.

### First Embodiment

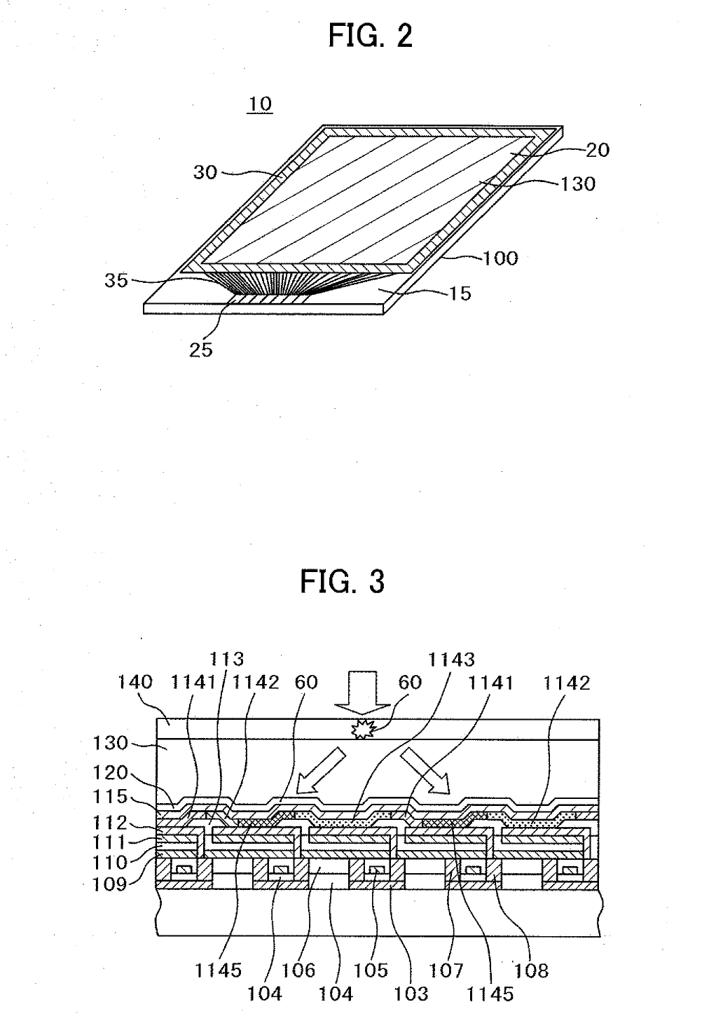

FIG. 2 is a perspective view of an organic EL display device 10 to which the present invention is applied. In FIG. 2, a display area 20 and a terminal area 15 are formed on a device substrate 100 of glass. The display area 20 is covered by an organic flattening film 130. The organic flattening film 130 and the display area 20 are substantially equal to each other. A peripheral sealing area 30, which is covered by an inorganic passivation film, is formed in the periphery of the display area 20 in which the organic flattening film 130 is not present. The organic film is permeable to the water, so that the organic flattening film 130 is removed in the peripheral sealing area 30.

The terminal area 15 is formed on the outside of the display area 20. In the terminal area 15, leader lines 35 of scan lines, image signal lines, and power lines are formed and connected to a terminal portion 25 of the terminal area 15. Scan signals, image signals, power, and the like, are supplied from the terminal portion 25.

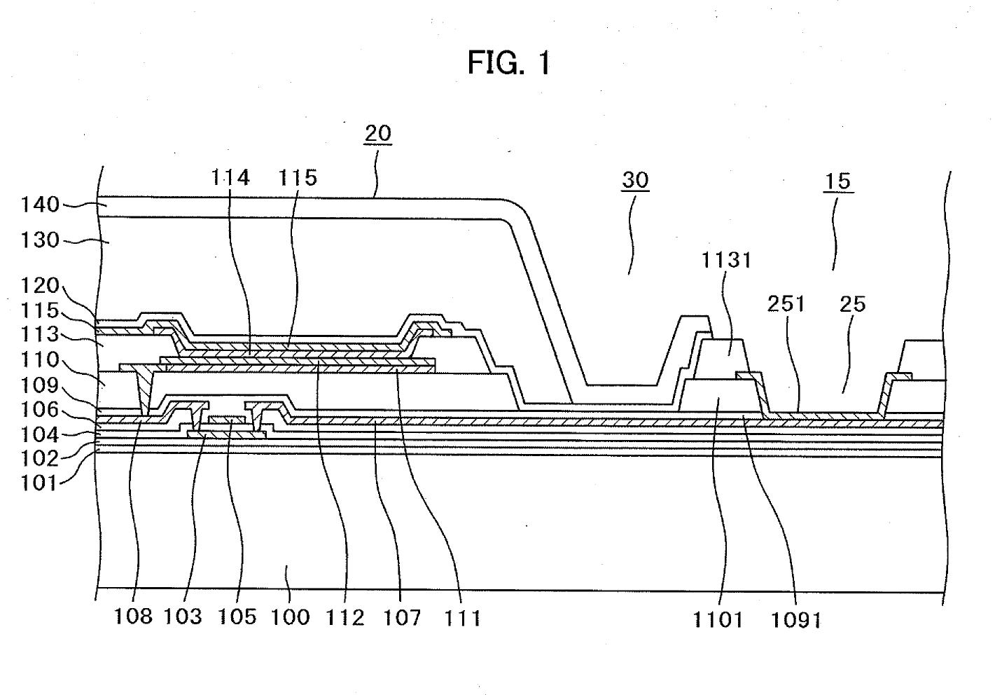

FIG. 1 is a schematic cross-sectional view of the structure of the present invention. FIG. 1 shows a cross section of a part of the display area 20, the peripheral sealing area 30, and the terminal area 15. The following description is made assuming that the organic EL display device 10 is the top emission type. However, the present invention is not limited to the top emission type, and can also be applied to the organic EL display device of the bottom emission type.

In the display area 20 of FIG. 1, a first base film 101 of SiN is formed on the device substrate 100 of glass, on which a second base film 102 of SiO₂ is formed. The role of the first base film 101 and the second base film 102 is to prevent the contamination of a semiconductor layer 103 by an impurity deposited from the glass substrate and degrading of the characteristics of the semiconductor layer 103.

The semiconductor layer 103 is formed on the second base film 102. In this embodiment, the semiconductor layer 103 is formed from poly-Si with a thickness of about 50 nm. The formation method of the poli-Si semiconductor layer 103 is as follows. First, an a-Si layer is formed. Then, the a-Si layer is converted to a poly-Si layer by annealing with an excimer laser or other means.

A gate electrode 105 is formed on the semiconductor layer 103. The gate electrode 105 is formed in the same layer of a gate wiring. A channel section, a source region, and a drain region are formed in the semiconductor layer 103. The source region and the drain region are formed by adding an impurity to the semiconductor layer 103 by ion implantation with the gate electrode 105 as a mask.

An interlayer insulating film 106 is formed from SiN or other suitable materials covering the gate electrode 105. A source line 108 and a drain line 107 are formed on the interlayer insulating film 106. In this embodiment, the image signal line is synonymous with the drain line 107. The current flows through the source line 108 and the drain line 107 to cause the organic EL layer 114 to emit light. For this reason, the source line 108 and the drain line 107 are formed thick with a thickness of about 700 nm, using Al which is a metal of low resistance. In the layer below the Al wiring, a barrier metal is formed from a high melting point metal such as Mo or Ti in order to prevent the contamination of the semiconductor and the like with Al. Above the Al wiring, a cap metal is formed from a high melting point metal such as Mo or Ti in order to prevent the hillock of Al.

The source line 108 and the drain line 107 are connected to a source region and a drain region in the semiconductor layer 103, respectively, by through holes formed in the gate insulating film 104 and the interlayer insulating film 106, respectively. Further, the drain line 107 extends to the terminal portion 25 through the peripheral sealing area 30. The source line 108 is connected to the lower electrode 112 of the organic EL layer 114.

A first inorganic passivation film 109 is formed from SiN or other suitable materials covering the source line 108 and the drain line 107. The role of the first inorganic passivation film 109 is mainly to protect the TFT from an external impurity. An organic passivation film 110 is formed on the first inorganic passivation film 109. The role of the organic passivation film 110 is to protect the TFT and to flatten the surface thereof. This makes it possible to form the organic EL layer 114 on the flattened surface, preventing the organic EL layer 114 from being cut off or disconnected.

On the organic passivation film 110, a reflection film 111 is formed from a metal having a high reflectance, such as Al or Ag. In this embodiment, the organic EL display device 10 is of the top emission type, in which the light generated in the organic EL layer 114 is reflected upward by the reflection film 111 to increase the light use efficiency.

On the reflection film 111, the lower electrode 112 is formed from ITO (Indium Tin Oxide) which is a transparent conductive film used for the anode of the organic EL layer 114. The ITO of the lower electrode 112 is connected to the source line 108 by the through hole formed in the first inorganic passivation film 109 as well as the organic passivation film 110.

The organic EL layer 114 is formed on the lower electrode 112. In general, the organic EL layer 114 is formed by plural layers. For example, a hole injection layer of 50 nm, a hole transportation layer of 50 nm, a light emitting layer of 20 nm, an electron transportation layer of 20 nm, and an electron injection layer of 1 nm from the anode side. Each of the layers is very thin. The total thickness of the five layers is only about 140 nm.

Further, banks 113 of acrylic resin or other resin are formed on the lower electrode 112 and the organic passivation film 110, in order to partition the individual pixels. As described above, the layers of the organic EL layer 114 are very thin. If there is a step in the layers, a cut-off occurs in the step portion. The bank 113 has a role to prevent the cut-off particularly in an end portion of the organic EL layer 114.

On the organic EL layer 114, the upper electrode 115 is formed from InZnO (Indium Zinc Oxide) which is a transparent conductive film used for the cathode of the organic EL layer 114. InZnO and ITO are both transparent conductive films. The difference is that InZnO has a lower resistance than ITO before annealing. The organic EL layer 114 is heat-sensitive, so that it is difficult to perform annealing after the organic EL layer 114 is covered. For this reason, InZnO is used for the cathode of the organic EL layer 114.

As described above, the side of the device substrate 100 of the organic EL display device 10 is typically completed. Then, since the organic EL display device 10 according to the present invention is of solid sealing, the upper electrode 115 is covered by the second inorganic passivation film 120 of SiN or other suitable materials. This is to protect the organic EL layer 114 from water. The thickness of the second inorganic passivation film 120 is about 200 nm.

The second inorganic passivation film 120 is further covered by the organic flattening layer 130. Examples of the material of the organic flattening film 130 include epoxy resin, thermoplastic polypropylene and polyethylene. The organic flattening layer 130 is formed thick with a thickness of about 30 μm by printing or film transfer. The thickness of the organic flattening film 130 can be set to the range of 10 μm to 100 μm, according to the specification of the organic EL display device product.

A third inorganic passivation film 140 is formed on the organic flattening layer 130. The third inorganic passivation film 140 is formed in such a way that SiN of about 1 μm is applied by a low temperature CVD such as plasma CVD or thermal CVD with tungsten wire as a catalyst. The outside water is mainly blocked by the third inorganic passivation film 140. The third inorganic passivation film 140 covers the entire surface except for the terminal portion 25. The third inorganic passivation film 140 is removed from the terminal portion 25 by photolithography or other suitable methods.

In FIG. 1, the drain line 107 passes through the peripheral sealing area 30 and is connected to the terminal. The first base film 101, the second base film 102, the gate insulating film 104, and the interlayer insulating film 106 are present below the drain line 107. The first inorganic passivation film 109, the second inorganic passivation film 120, and the third inorganic passivation film 140 are present above the drain line 107. In other words, the organic film is impermeable to the water, so that the peripheral sealing area 30 is sealed only by the inorganic film.

In FIG. 1, the drain line 107 extends to the terminal area 15, in which image signals are supplied from the terminal portion 25. The drain line 107 is mainly formed from Al, and is likely to be eroded by the outside environment. Thus, the terminal portion 25 of the drain line 107 is covered by a terminal portion conductive film 251 formed from ITO. ITO of the terminal portion conductive film 251 is formed in the same layer of the lower electrode 112.

The drain line 107 extending to the terminal area 15 is covered by a protective film 1091 formed in the same layer of the first inorganic passivation film 109, a protective film 1101 formed in the same layer of the organic passivation film 110, and a protective film 1131 formed in the same layer of the bank 113. In this way, the drain line 107 is protected from the outside atmosphere.

When the pinhole 60 and the like are present in the third inorganic passivation film 140 in the display area 20, the water entering from the pinhole 60 has an adverse effect on the organic EL layer 114. FIG. 3 is a cross-sectional view of the display area 20, showing a case in which the pinhole 60 is present in the third inorganic passivation film 140. The cross-sectional view of FIG. 3 is simplified, but the basic configuration is the same as described in FIG. 1.

In FIG. 3, a red light emitting layer 1141, a green light emitting layer 1142, and a blue light emitting layer 1143 are arranged in parallel constituting the organic EL layer 114 on the lower electrode 112. The boundaries of the red light emitting layer 1141, the green light emitting layer 1142, and the blue light emitting layer 1143 are present on the banks 113. The upper electrode 115 is formed to cover the organic EL layer 114. The second inorganic passivation film 120, the organic flattening film 130, and the third inorganic passivation film 140 are formed on the upper electrode 115.

In FIG. 3, the pinhole 60 occurs in the second inorganic passivation film 120. The water enters from the pinhole 60 as indicated by the arrow. The water diffuses into the organic flattening film 130, for example, as indicated by the arrows. The water diffuses into the organic flattening film 130 and reaches the second inorganic passivation film 120. If the second inorganic passivation film 120 is perfect, the water is blocked by the second inorganic passivation film 120 and does not enter the organic EL layer 114.

However, the second inorganic passivation film 120 is formed on the upper electrode 115 having concaves and convexes with the banks 113 and the like. For this reason, the possibility of the presence of the pinhole 60 in the second passivation film 120 is greater than the third inorganic passivation film 140. When the pinhole 60 is present in the second inorganic passivation film 120 as shown in FIG. 3, the water enters through the pinhole 60.

The upper electrode 115 is thin, in which more pinholes 60 are present than in the second inorganic passivation film 120. Thus, the water reaches the organic EL layer 114. In particular, the water reacts with and inactivates the alkali metal or other metal of the electron injection layer. As a result, the light emission efficiency of the organic EL layer 114 is reduced.

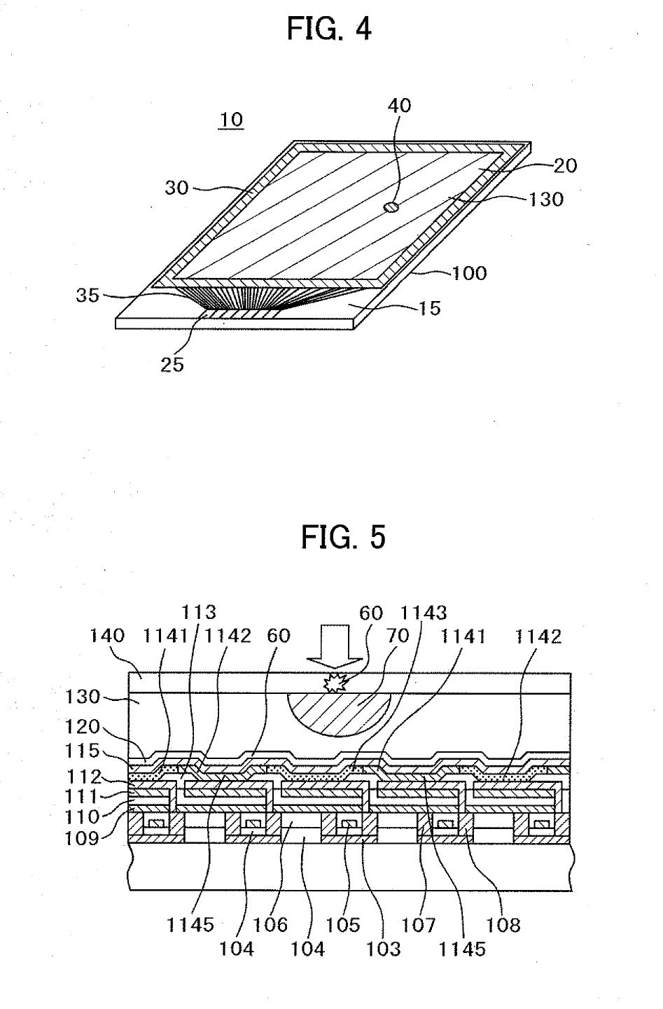

FIG. 3 shows the state in which part of the green light emitting layer 1142 and the red light emitting layer 1141 is degraded by water. In FIG. 3, reference numeral 1145 denotes the portions in which the green light emitting layer 1142 and the red light emitting layer 1141 are degraded. When the light emitting layer is degraded by water, a dark spot 40 occurs in the display area 20 as shown in FIG. 4. In this case, if the dark spot shown in FIG. 4 occurs immediately after the completion of the organic EL display device 10, the specific organic EL display device 10 is found to be defective and is not delivered to the market.

However, the water entering from the pinhole 60 of the third inorganic passivation film 140 diffuses into the organic flattening film 130 at a lower speed. The dark spot 40 does not occur for a period of time from the completion of the product to the deliver to the market. In such a mechanism, the time for which the dark spot 40 occurs is several months after the completion of the organic EL display device 10. In other words, the product has already been delivered to the market when the dark spot 40 occurs, resulting in a defect in the market.

In order to prevent such a defect in the market, according to the present invention, the pinhole 60 present in the third inorganic passivation film 140 is detected in the plant, thereby preventing the organic EL display device 10 in which the pinhole 60 is present in the third inorganic passivation film 140 from being delivered to the market. FIG. 5 is a cross-sectional view of the first embodiment. The configuration of FIG. 5 is as follows.

That is, a material capable of reacting with oxygen is added to the organic flattening film 130. When the oxygen enters through the pinhole 60 of the third inorganic passivation film 140, the specific material reacts with the oxygen and exhibits color. By means of this phenomenon, the pinhole 60 of the third inorganic passivation film 140 is found. Then, the organic EL display device 10 in which the pinhole 60 is present in the third inorganic passivation film 140 is prevented from being delivered to the market.

Here, the material capable of reacting with oxygen is added to the organic flattening film 130, instead of the material capable of reacting with water. This is because oxygen is the most reactive element in the air, so that the reaction with the added material can be detected with a high sensitivity. The purpose is to determine the presence of the pinhole 60 in the third inorganic passivation film 140, which can be achieved either by water or by oxygen.

In this case, the base material of the organic flattening film 130 is epoxy resin, thermoplastic polypropylene or polyethylene, or other suitable resin. Further, pigments such as indigo carmine and methyl blue are preferable for the additive capable of reacting with oxygen and exhibiting color. Such reductants are oxidized and exhibit blue color.

The additive capable of reacting with water may be used in the detection of the pinhole 60. An example of the system capable of reacting with water and exhibiting color is a mixture of small quantities of phenolphthalein and sodium carbonate. Sodium carbonate absorbs moisture and turns into alkali, causing the phenolphthalein to exhibit red color. In this case, thermoplastic polypropylene or polyethylene can be used as the base material of the organic flattening film 130. However, epoxy resin is not preferred because it prevents the cross-linking reaction.

Both in the case of the detection of oxygen and in the case of the detection of water, the base material of the organic flattening film 130 preferably contains about 0.5 to 2 percent by weight of the additive. In FIG. 5, when oxygen enters from the pinhole 60 in the third inorganic passivation film 140, the additive, or the pigment, reacts with the oxygen and exhibits color. For example, in FIG. 5, when indigo carmine is added, the reductant reacts with the entering oxygen and exhibits blue color. This can be observed as a blue spot from the surface as shown in FIG. 5.

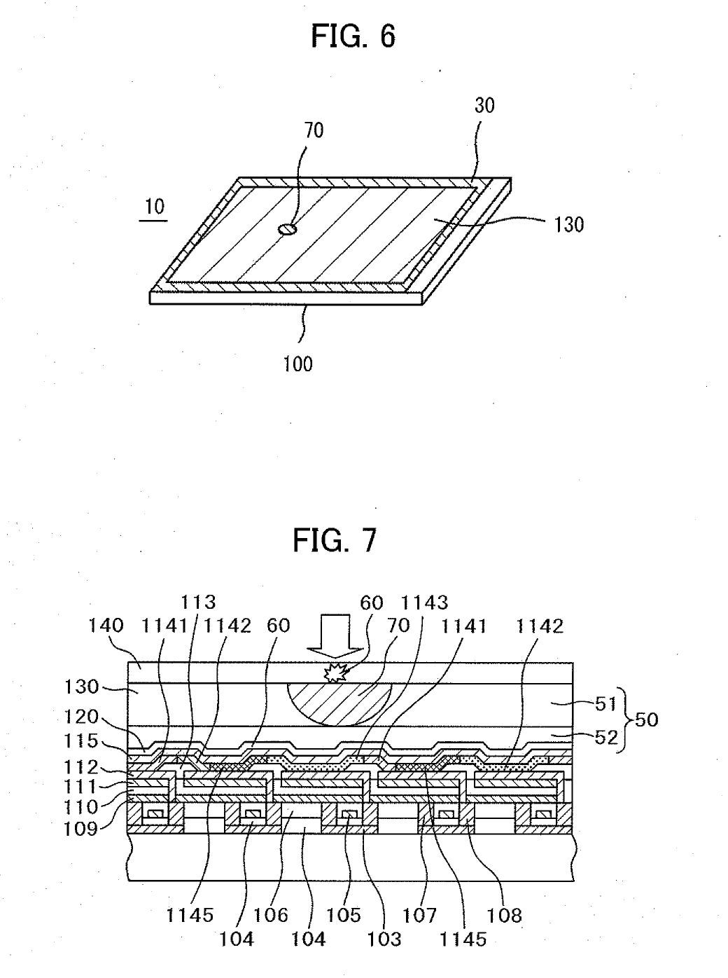

When the organic EL display device 10 is lit in white, as shown in FIG. 6, the portion in which the pinhole 60 is present can be recognized as a blue point. This makes it easy to pick up the defective product. In addition to indigo carmine, other pigments such as methylene blue can also be used for this purpose.

For example, the pigment of indigo carmine or methylene blue is added to epoxy resin which is the base material of the organic flattening film 130, and then the epoxy resin is applied and cured. Another method is to apply and cure epoxy resin which is the base material of the organic flattening film 130, followed by applying epoxy resin to which the pigment of indigo carmine or methylene blue is added as described above. After that, the entire surface of the organic flattening film 130 is covered by the third inorganic passivation film 140. The above description is made assuming that the base material of the organic flattening film 130 is epoxy resin. However, other resin can also be used.

### Second Embodiment

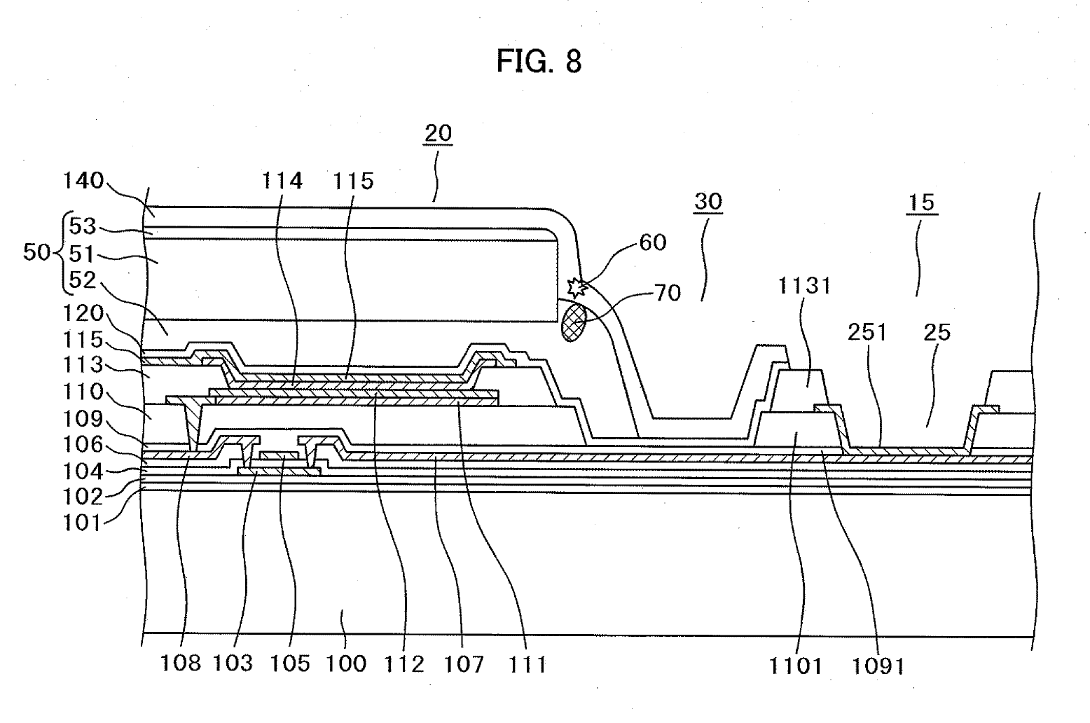

FIG. 7 shows a second embodiment. The second embodiment is different from the first embodiment in that the organic EL layer 114 is protected from water by a laminate film 50, instead of using the organic flattening film 130. In FIG. 7, the second inorganic passivation film 120 is formed on the upper electrode 115 of the organic EL layer 114, which is the same as the configuration of the first embodiment. However, in the second embodiment, the laminate film 50 is formed on the second inorganic passivation film 120. Then, the third inorganic passivation film 140 is formed on the laminate film 50. The laminate film 50 includes a laminate film base material 51 and a thermoplastic adhesive material 52.

The third inorganic passivation film 140 is formed on the laminate film 50. At this time, an SiN film of about 1 μm is applied by a low temperature CVD. The surface of the laminate film 50 is very flat with few bubbles or other defects. The number of defects in the third inorganic passivation film 140 can be further reduced compared to the organic flattening film 130 formed by printing or application.

In this embodiment, a surface of the laminate film base material 51 is dyed with indigo carmine or methylene blue. Further, the thermoplastic adhesive material 52 is applied to the other surface of the laminate film base material 51. Then, sodium hydrosulfite solution is used as a reductant to fade the pigment, which is then dried with oxygen blocked out. Then, the laminate film 50 prepared as described above is laminated on the second inorganic passivation film 120 of the organic EL display panel. Then, the third inorganic passivation film 140 is formed on the laminate film 50 by a low temperature CVD.

When oxygen is transmitted through the pinhole 60 present in the third inorganic passivation film 140, the dye applied to the base material of the laminate film 50 reacts with the oxygen and exhibits blue color. In this way, it is possible to detect the defect in the third inorganic passivation film 140. When water passes through the pinhole 60 of the third inorganic passivation film 140, a colored portion 70 is generated in the organic EL display device 10 as shown in FIG. 6. In this way, it is possible to detect the defect in the third inorganic passivation film 140.

### Third Embodiment

FIG. 8 is a cross-sectional view showing a third embodiment of the present invention. FIG. 8 is a cross-sectional view, similar to FIG. 1, from the end portion of the display area 20, to the peripheral sealing area 30 and the terminal area 15. In FIG. 8, the second inorganic passivation film 120 is formed on the upper electrode 115 of the organic EL display 114, which is the same as the first embodiment. In the third embodiment, the laminate film 50 described in the second embodiment is laminated on the second inorganic passivation film 120. Further, in the third embodiment, a barrier layer 53 for blocking water is provided by co-depositing alumina and silica on a surface of the laminate film base material 51. Then, the third inorganic passivation film 140 is formed on the barrier layer 53 by a low temperature CVD.

As described above, in this embodiment, the barrier layer 53 is provided on the surface of the laminate film 50, so that little water is transmitted through the laminate film 50. As a result, the defect associated with the water transmission is limited to the peripheral portion.

In this embodiment shown in FIG. 8, the cobalt chloride powder is added to the thermoplastic adhesive material 52. When water enters from the pinhole 60 in the periphery of the third inorganic passivation film 140, the cobalt chloride turns from blue to pale red. In this way, it is possible to detect the defect in the inorganic passivation film 140. It should be noted that the thermoplastic adhesive material 52 is blue, but is transparent and colorless in the display area 20 because the thermoplastic adhesive material 52 is very thin. However, as shown in FIG. 8, the thermoplastic adhesive material 52 extends beyond the laminate film 50 and increases in thickness in a peripheral portion of the laminate film 50, in order to detect the change in color.

In FIG. 8, the entering water is found due to the occurrence of the colored portion 70. In this case, the colored portion 70 is once dried and returned to blue. Then, the third inorganic passivation film 140 is deposited again on the barrier layer 53 for restoration. The restoration can be performed by forming the inorganic passivation film on the entire surface again. Another method of restoration is to partially form the inorganic passivation film by applying TEOS (tetraethoxysilane) and by irradiating a laser beam.

The presence of water can be detected by adding a power of an alkali metal, for example, sodium carbonate, as well as phenolphthalein, to the thermoplastic adhesive material 52. When water is present, it shows alkaline property with phenolphthalein exhibiting red color, and turns to colorless when dried.

The above embodiments have been made assuming that the organic EL display device is of the top emission type. However, the present invention can also be applied to the organic EL display device of the bottom emission type. In the organic EL display device of the bottom emission type, unlike the organic EL display device 10 is of the top emission type as shown in FIG. 1 and other figures, the reflective electrode below the lower electrode 112 of the organic EL layer 114 is removed. Further, the upper electrode 115 is formed from a metal with a high reflectivity such as Al or Ag, instead of using InZnO. In this case, the upper electrode 115 is the cathode. Except for such differences in the configuration, the basic configuration is the same in the top emission type and the bottom emission type. Thus, the present invention can be applied to the bottom-emission organic EL display device without any problems.

What is claimed is:

1. An organic electroluminescence display device comprising a display area in which pixels, each having a TFT and an organic EL layer interposed between a lower electrode and an upper electrode, are arranged in a matrix form,
wherein a first inorganic film is formed on the upper electrode,
wherein an organic film is formed on the first inorganic film,
wherein a second inorganic film is formed on the organic film, and
wherein a material capable of reacting with oxygen and exhibiting color is added to the organic film.

2. The organic electroluminescence display device according to claim 1, wherein the organic film is epoxy resin, polypropylene resin, or polyethylene resin.

3. The organic electroluminescence display device according to claim 2, wherein the material capable of reacting with oxygen and exhibiting color is indigo carmine or methylene blue.

4. The organic electroluminescence display device according to claim 3, wherein the organic film contains 0.5 to 2 percent by weight of the material capable of reacting with oxygen and exhibiting color.

5. An organic electroluminescence display device comprising a display area in which pixels, each having a TFT and an organic EL layer interposed between a lower electrode and an upper electrode, are arranged in a matrix form,
wherein a first inorganic film is formed on the upper electrode,
wherein an organic film is formed on the first inorganic film,
wherein a second inorganic film is formed on the organic film, and
wherein a material capable of reacting with water and exhibiting color is added to the organic film.

6. The organic electroluminescence display device according to claim 5, wherein the organic film is polypropylene resin or polyethylene resin.

7. The organic electroluminescence display device according to claim 6, wherein the material capable of reacting with water and exhibiting color is a mixture of phenolphthalein and sodium carbonate.

8. The organic electroluminescence display device according to claim 7, wherein the organic film contains 0.5 to 2 percent by weight of the material capable of reacting with water and exhibiting color.

9. An organic electroluminescence display device comprising a display area in which pixels, each having a TFT and an organic EL layer interposed between a lower electrode and an upper electrode, are arranged in a matrix form,
wherein a laminate film including an adhesive material and a base material is provided on the upper electrode,
wherein a pigment is applied to the base material of the laminate film,
wherein an inorganic film is formed on the laminate film, and
wherein the pigment is a material capable of reacting with oxygen and exhibiting color.

10. The organic electroluminescence display device according to claim 9, wherein the material capable of reacting with oxygen and exhibiting color is indigo carmine or methylene blue.

11. An organic electroluminescence display device comprising a display area in which pixels, each having a TFT and an organic EL layer interposed between a lower electrode and an upper electrode, are arranged in a matrix form,
wherein a laminate film including an adhesive material and a base material is provided on the upper electrode,
wherein a barrier layer for blocking water is formed on the base material of the laminate film,
wherein an inorganic film is formed on the laminate film, and
wherein a material capable of reacting with water and exhibiting color is added to the adhesive material.

12. The organic electroluminescence display device according to claim 11, wherein the barrier layer is formed by co-depositing alumina and silica.

13. The organic electroluminescence display device according to claim 11, wherein the material capable of reacting with oxygen and exhibiting color is cobalt chloride.

14. The organic electroluminescence display device according to claim 11, wherein the material capable of reacting with oxygen and exhibiting color is a mixture of sodium carbonate and phenolphthalein.
